(19) United States
(12) Patent Application Publication
(10) Pub. No.: US 2012/0125403 A1
(43) Pub. Date: May 24, 2012

(54) Photovoltaic Flat Panel With Enhanced Acceptance Angle Comprising Micro-Lens Array In Laminating Film

(75) Inventor: Raul Maria Orlandi, Cerro Maggiore (IT)

(73) Assignee: WORLD PATENTS IMPROVEMENT COMPANY WOPIC S.A., Luxembourgville (LU)

(21) Appl. No.: 13/382,409

(22) PCT Filed: Jul. 6, 2010
(86) PCT No.: PCT/IT10/00301

§ 371 Date: Jan. 5, 2012

(30) Foreign Application Priority Data
Jul. 9, 2009 (IT) MI2009A001225

(51) Int. Cl. H01L 31/052

(52) U.S. Cl. 136/246

(57) ABSTRACT

The integrated system for the conversion of solar energy into eco-compatible energy, comprises panels destined for the reception of solar rays, and is characterized by the presence in the panels of:
A plastic film bearing micro-incisions that form an array of multi-focal holographic micro-lenses (m1, m2) of infinitesimal size, capable of being positioned on the panel in a random manner, or
A pair of plastic films superimposed on each other, bearing on their inner and outer surfaces micro-undular forms capable of creating a series of micro-lenses (c1, c2) of an off-spherical shape and infinitesimal size, having different refraction indices and capable of being positioned on the panel in a random manner.

The object of this invention is an integrated system for the production of structures with a high energy converting efficiency, for the purpose of converting solar energy into eco-compatible energy.

Over the past 20 years, industrialized countries have witnessed an exponential increase of the demand for energy.

The demand for alternative energies, such as wind and solar energy is in a phase of growth. One of the most widespread methods is the use of “solar cells” exploiting the photoelectric effect of a p-n junction and generating energy from the light impinging upon them.

However, their maximum efficiency presupposes their total exposure toward the lighting source (the sun).

Based on the present technology, the sunlight capturing devices (thermal and photovoltaic panels) are constituted of a tightly sealed container harboring the electricity utilizing device (photovoltaic cells) or the thermo-hydraulic device (finned heat-exchanger tubes) and a transparent topside closing plate (made of glass or plastic material). The topside plate is designed to protect the delicate content, but must at the same time allow the passage of a maximum possible amount of the solar radiation impinging upon it.

These manufactured items are normally placed on the slopes of roofs and prevalently oriented toward south.

Independently of the best overall orientation that can be accomplished, it remains a fact that the motion of the sun during the day (an arc-like motion from east to west) allows receiving a fair amount of penetrating radiation, inside a perfectly oriented solar panel, only over a portion of an arc of about 50° (centrally positioned at 25°-25° with respect to a line perpendicular to the panel), and when the sun is outside an arc of about 82° (41°-41°) the penetrating radiation is even nil; there is a so-called total reflection by the protective glass.

The radiation impinging on a flat plate (refer to Snell's Law) breaks-up in fact into a reflected portion and another portion that after being refracted passes the plate and, in our case, becomes the fraction useful for converting to electricity (photovoltaic panels) or to heat (thermal solar panels).

Having made this premise, reference is made to FIG. 1 where the number 1 indicates a glass plate, 2 the darkened areas of total reflection, 3 an impinging beam of light, 4 a refracted beam, and 5 a reflected beam. Considering the refractive index of the glass sine(r)/sine(i) to be 1.5, it follows that i=arsine (0.066)=41° for r=90°. When the impinging angle “i” exceeds 41°, the refracted radiation therefore becomes nil, and all the impinging radiation is reflected and thus lost for the panel. However, even within the useful 82° of the arc, when passing from an impingement angle of zero (rays perpendicular to the plate) to the limiting angle (41° both from one side to the other), the refractive intensity is gradually decreasing until it falls to zero.

FIG. 2 shows a traditional diagram of the power delivered during the sunlight hours by a thermal panel (collector), whose ordinate lists the power delivered in kW/m², the abscissa the hourly passing of a day, 6 represent the flux of energy in space, 7 the diagram of the collector for a total reception, 8 the diagram of a fixed tilting collector, 9 the average power delivered by a fixed tilting collector, and 10 the average of a collector for a total reception. It can be observed that there is a peak corresponding to the central hours of the day (at around 13 hours) and the graph (FIG. 2) shows that the power is satisfactory only for an overall period of about 6 hours.

In order to boost the amount of the delivered energy, the present state of the art proposes, in order to keep a panel perpendicular to the sun, a mechanical solution, meaning a physical shifting (orientation) of the panel obtained by a motor and a mobile frame; this achieves the result of maintaining the glassy surface of the panel in a position adequately perpendicular to the impinging solar rays; this achieves an extension of the satisfactory power delivery period up to about 14 hours in the summer.

This technology is known as a “solar pursuit” and can, under ideal conditions using two motorized axes and photovoltaic panels, achieve a boost of the delivered energy up to 70%. This technology is however very expensive and not employed for domestic installations, but only for large power stations and special applications.

There are other systems capable of boosting the energy that impinges on the capturing (thermal or photovoltaic) solar device:
1. A first system utilizing a park of static and turning mirrors (performing a solar pursuit),
2. Other systems utilizing large lenses that concentrate the captured energy on a limited surface.

Both of these systems are extremely expensive and suitable only for large installations, or they comprise other intrinsic limitations.

The solar cell converts solar energy into electrical energy, so that the problem of securing more energy resides in the availability of larger amounts of solar energy to be conveyed onto the solar cells. In order to increase the amount of solar energy on the individual cell, one method is to utilize an optical lens so that the focusing lens can concentrate the solar rays. However, as the sun's position changes with respect to the solar cell's position, the expected increase of solar energy is minimized when the sun's inclination changes with respect to the lens focusing the solar rays on the cell, except in the case of a directional use of the cell, so as to keep it perpendicular to the solar rays at all times (active tracking).

As concerns the present state of the art pertaining to photovoltaic panels, it must be mentioned that the photovoltaic panels are constituted of a glass plate, an EVA-sheet, a layer of silicon cells set side by side, another EVA-sheet and a protective sheet known as a “Tedlar”®, the whole being generally inserted into an aluminum frame. The silicon cells are flat, of a standard size such as 10 cm×10 cm with a thickness varying from 100 to 300 micron, and interconnected by joints (known as “ribbons”) in electrical circuits set up in series or parallel.

Only 1% of the photovoltaic panels uses solar light concentrating systems to boost efficiency. These light concentrating systems employ lenses or parabolic mirrors that focus and concentrate the sun light to boost efficiency but are not applicable to standard panels and require costly structures to support the lenses and mirrors at the distances determined by the individual cells, which are in turn mounted on the panels at a distance from each other. In order to keep the cone of light obtained from the lenses and mirrors at a constant value, it is also necessary to construct a solar pursuit system active throughout the arc of the day.

There are further systems utilizing holographic lenses or plates capable of concentrating or conveying the daylight onto photovoltaic cells, but these present other applicative limitations and drawbacks.

The document US2007/0107770 in fact describes a photovoltaic system to convert solar energy into electrical energy, which avails itself of a refracting material bearing holograms endowed with the function of focusing and concentrating the impinging sunlight on columns of photovoltaic cells that are substantially distanced from each other and the superimposed layer of refracting material.

The document US2008/0257400 describes a photovoltaic system fitted with holographic lenses realized on two parallel substrata and capable of concentrating the light on photovoltaic cells interposed between the strata perpendicular to the same. The systems provide a rigid supporting structure for the substrata and the cells.

The document WO2008/071180 describes a photovoltaic systems for converting sunlight into electrical, energy that comprises a plane of support for a series of photovoltaic cells and a transparent plate set up at a certain distance from the cells and bearing holograms capable of concentrating the light impinging on each underlying cell, while for each cell the area of the plate impinged upon by the light is greater than the area of the underlying cell.

The holographic devices described in the abovementioned documents are essentially based on concentrating lenses and presuppose the presence of structures capable of distancing the holographic layers from the underlying panels bearing the photovoltaic cells.

The documents WO00/74147 describes a device that concentrates optical radiations on a support of photovoltaic cells that are substantially distanced from each other. It is constituted of a film mounted on at least one transparent flat plate bearing holographic micro-incisions that are forming angularly and spectrally multiplexed refractive structures laterally surrounding the cells that are set up under the plate. The optical radiations impinging on the sides of the photovoltaic cells are thus reflected along the plate and concentrated on the plates themselves.

The document U.S. Pat. No. 5,877,874 describes a planar light concentrating device comprising a transparent plate that carries a film containing angularly and spectrally multiplexed refractive holographic micro-incisions which are forming a structure capable of trapping light within the plate and conveying it toward a utilizing device mounted at the rim of the plate, such as for instance an optical fiber unit, a water reservoir to be heated or a photovoltaic cell unit.

The photovoltaic film acts in this case as a sunlight mirror and uses the glass of the plate as a guide for the light.

### SCOPE OF THE INVENTION

The scope of the invention is to create an integrated system for the production of structures having a high energy converting efficiency, for converting solar energy into eco-compatible energy, so as to offer, with respect to the known art, at least one of the following distinguishing advantages and features:
It does not require creating distancing structures capable of distancing the films of (holographic or non-holographic) lenses from the underlying photovoltaic panel, so that according to the invention, the film(s) may even be applied inside the photovoltaic panel itself;
It does not merely have the function of concentrating the light on the cells of the panel, but rather that of maximizing the amount of light impinging on the cells over the arc of a day;
According to the invention, it does not involve the need of allocating the film by calibrating its position on the underlying silicon cells, because the holographic or non-holographic film lenses can, because of their infinitesimal dimensions, be positioned in a random manner;
The film according to the invention may be utilized on cells of any profile or size, even on panels of amorphous silicon or panels of any other nature suitable for converting solar light into energy;
The film according to the invention can be applied on already installed panels, by utilizing the in-place laminating technology already employed for the application of “heat-preventing” films on window glasses;
The system involves rather limited production and installation costs.

### ABSTRACT OF THE INVENTION

The integrated system according to the invention for the production of structures with a high energy converting efficiency for converting solar energy into eco-compatible energy provides for this purpose the use of panels destined for the reception of solar rays, and is characterized by the presence on the same of:
A plastic film bearing micro-incisions realizing a whole of holographic multifocal micro-lenses (m1, m2) of infinitesimal dimensions, capable of being positioned on the panel in a random manner, or
A couple of plastic films (c1, c2) superimposed on each other, bearing on their inner and outer surfaces a series of micro-lenses of an off-spherical profile and infinitesimal dimensions, having different refractive indices and capable of being positioned on the panel in a random manner.

### LIST OF DRAWINGS

The characteristics of the invention will become more evident from the description to follow, made with reference to the attached drawings, whose figures illustrate:

FIG. 1: A drawing schematically illustrating the relationship between the impinging, reflected and refracted ray in the case of a ray impinging on a transparent flat plate;

FIG. 2: A diagram of the power delivered by a thermal panel during the hours of sunshine;

FIG. 3: A drawing schematically illustrating the refraction of the light ray in the case of feeding the photovoltaic cell through a lens;

FIG. 4: Schematic drawings illustrating various possible profiles of multifocal lenses;

FIG. 5: An example of a lenticular profile capable of maximizing the flow of lateral light;

FIG. 6: A drawing schematically illustrating the behavior of a ray of light passing a lens with two faces having a different refractive index;

FIG. 7: An example schematically illustrating the functional principle of a complex lens obtained by coupling together opposing off-spherical lenses;

FIG. 8: An example schematically illustrating the method of obtaining a holographic lens equivalent to a traditional lens, such as for instance that shown in FIG. 7.

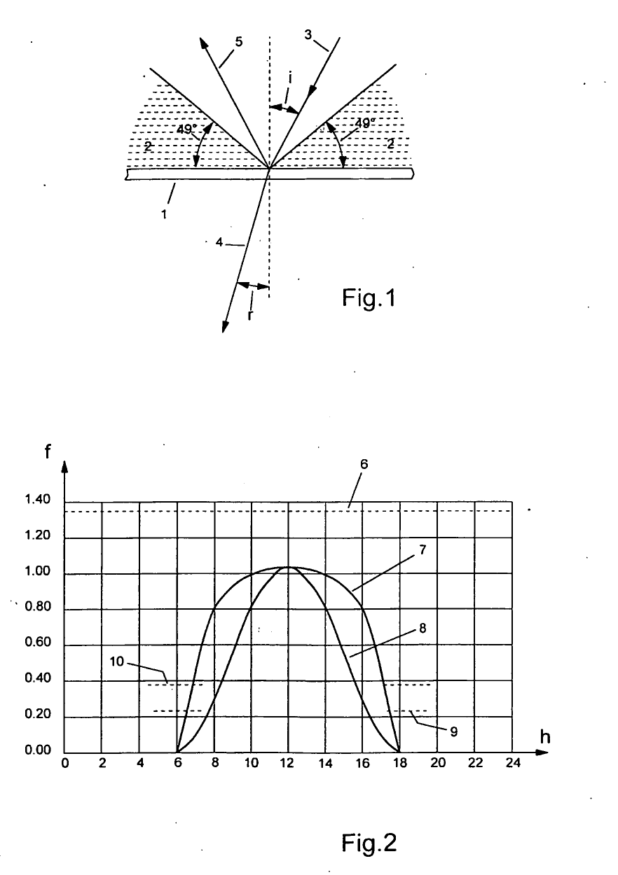

In order to better grasp the invention's functional principles, a premise on the following theoretical considerations is made.

The energy capable of being derived from sunlight is also a function of the latitude, hour and angle of impingement of the solar rays.

The density of radiating power received by the earth's surface at a latitude of 0° and with the sun at the azimuth, frequently referred to by S, attains an approximate peak value of 1 kW/m² depending on many factors. In attempting to capture this energy by absorbing it on a perfectly black body, the equilibrium temperature is obtained by the well known equation:

S=k*T*exp4

where k equals the Boltzmann constant leading to T=364° K, which is precisely the boiling point of water.

One of the methods for boosting the energy yield of a photovoltaic system is that of using solar energy “concentrators” based on lenses or mirrors of various types. If this holds true for thermal systems, the approach substantially differs for photovoltaic systems. The temperature of the photovoltaic cell must be the lowest possible, less than 65° C., its efficiency is otherwise drastically reduced. It is moreover necessary to consider the cells' efficiency at the various wavelengths of the received light. Above 1200 nm the efficiency is greatly reduced, which means that the upper portion of the light spectrum, above 1200 nm (infrared light), which represents about 25% of the solar emission, is not utilized and even harmful, as it determines an increase of heat at the junction of the photovoltaic cell.

Another important aspect relates to the uniformity of the radiation on the cell. A non-uniform distribution of the energy received from the sun on the panel leads to a drastic reduction of conversion efficiency. This is due to the Joule effect resulting from the serial resistances of the cells. The loss of efficiency can be derived from the formula:

Eff=Voc*Isc*FF/PI

where:

Voc=open circuit voltage

Isc=short circuit current

FF=filling factor

PI=solar power

It is therefore always necessary to consider the radiating model of any solar receiver or concentrator.

A further consideration is about the illuminating direction of the solar rays impinging on a photovoltaic cell. Two considerations are most important: the reflection of the light on the receiving surface and the diminution of efficiency due to the lesser quantity of energy per unit surface.

The photovoltaic cells are normally covered by glass with a refractive index of about 1.5. This means that the received light is, above a certain angle defined by Snell's law (about 41°) almost entirely reflected and thus drastically reducing the cell's efficiency. A few systems can eliminate this drawback by utilizing for instance glasses of low refractive index or anti-reflection devices (coatings or glazing), which are in any case absorbing a portion of the light.

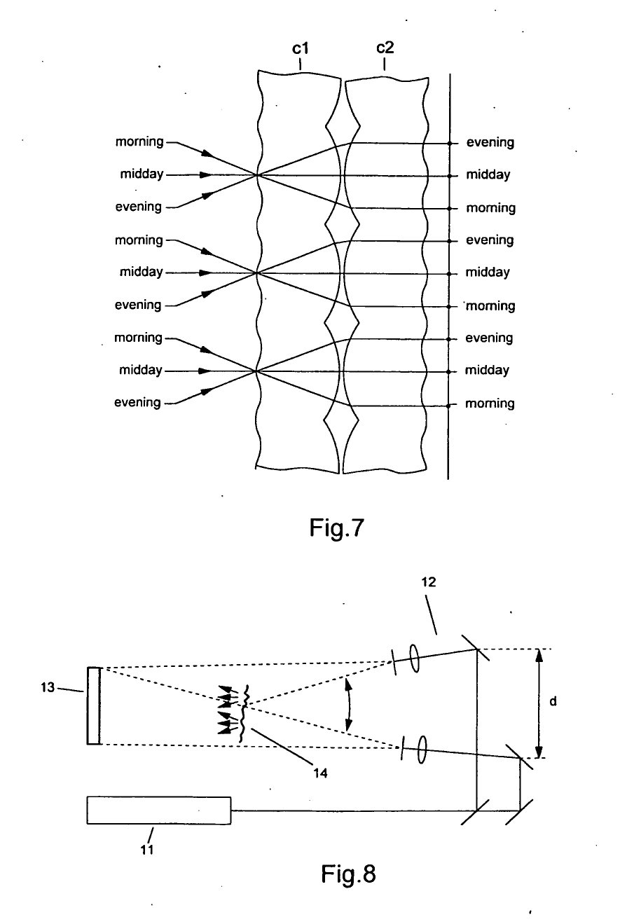

This limitation is due to the varying angle of impingement of the solar rays on the panel in the course of the day, and can be overcome by the solution principle at the heart of this invention, which essentially consists in applying the following material on each panel:
A plastic film bearing micro-incisions realizing an array of multifocal holographic micro-lenses (m1, m2, FIG. 4) of infinitesimal dimensions, capable of being positioned on the panel in a random manner, or
A pair of plastic films (c1, c2, FIG. 7) superimposed on each other, whose inner and outer surfaces are bearing micro-undulations capable of realizing a series of micro-lenses of an off-spherical profile, having different refraction indices and capable of being positioned on the panel in a random manner.

One possibility of overcoming the limitation imposed by the variation of the angle of impingement of the solar rays on the panels in the course of a day is in fact that offered by a lens being endowed in its structure with the possibility of generating multiple foci, while still keeping the individual lens dimensions unchanged.

For exemplifying purposes, FIG. 4 schematically illustrates the profiles m1 and m2 of two lenses with multiple foci. The figure also illustrates that impinging rays having an angle of impingement □ greater than 41° are deflected and not totally reflected. Classical optics will not allow the construction of industrially producibile lenses simultaneously having several foci. However, there is a technology available for creating complex lenses having multiple foci, which affords a definitive solution for the need of achieving multiple solar energy concentrators on photovoltaic cells, without altering their surface. This technology is realized by employing holography. A series of technologies (see for instance the Italian Patent no. 1217385 and the Italian patent application no. MI2007A001524, whose inventor is the same of the present invention) can produce holographic matrices capable of generating multiple holographic lenses at an extremely accessible industrial cost.

Another possibility for overcoming the formerly mentioned limitation is offered by the property of deviating a ray of light in two series of superimposed lenses having of an off-spherical profile and different refractive indices.

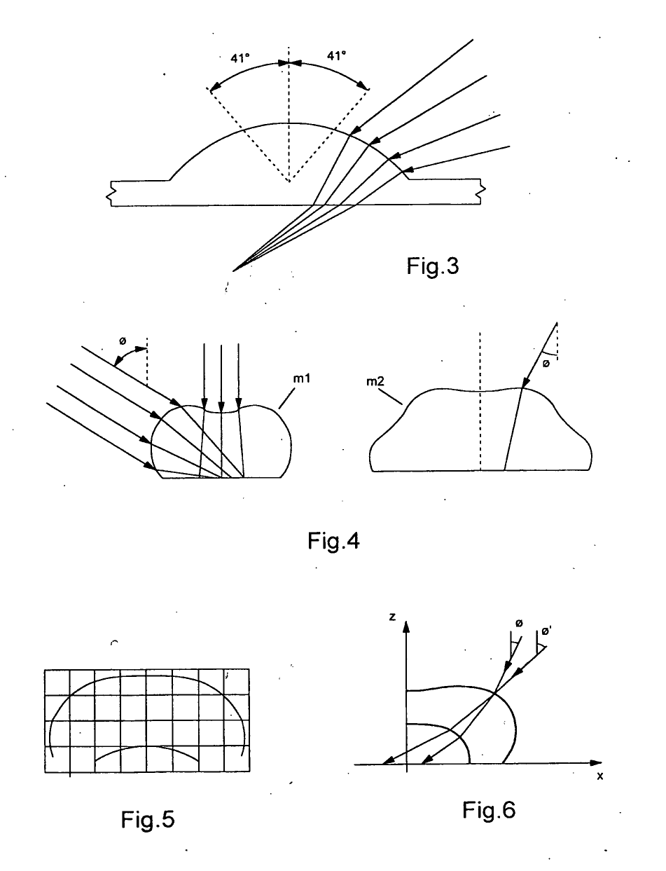

As can be seen in FIG. 3, the rays impinging laterally on the lens are in fact deflected rather than reflected, and are therefore partially utilized by the photovoltaic cell. If the problem is analyzed from a mathematical angle, it can be seen that it is a matter of resolving a lenticular profile capable of maximizing the flow of lateral light received from the sun. The problem is bound up with the maximum efficiency that can be obtained when the inclination of the solar rays amounts to an angle □.

The calculation of the best profile can be based on the use of analytical or graphical methods.

The use of iterative methods of calculation allows achieving the best profile of a hypothetical micro-lens resting on an individual photovoltaic cell. An example of the profile obtained by such calculations is given in FIG. 5.

It can be demonstrated (etendu of Lagrange) that in order to improve the lighting angle it is necessary to use two surfaces with suitably different refractive indices (refer to the schematic diagram of FIG. 6).

The problem therefore boils down to calculating the theoretical profile of a lens having two surfaces with a different refractive index. These calculations lead to superimposing two lenses having an off-spherical profile and different refraction indices.

In essence, it can be demonstrated that the same effect is achieved by two systems of off-spherical micro-lenses of an appropriate profile, such as for instance shown on an enlarged scale in FIG. 7 (on micro-lenses having an actual diameter of 0.2-0.3 mm). It can in fact be seen that if the foci of the lenses are suitably calculated, the solar rays are always made to converge in parallel on the surface of the photovoltaic cell, thus boosting its efficiency.

It is evident that a proper choice of the refraction index and thus of the material composing the lenses is a must. It is also necessary that such surfaces, especially the one exposed to the outside, must not pick up dust or debris, be blooming and as thin as possible.

This system (FIG. 7) allows an understanding of the fact that the functional principle of the classic lenses utilized with holographic lenses proves to be more practical and economical.

Theory has made it known that any type of holographic lenses can be made with the same characteristics of classic lenses. The “zone plate” is in fact nothing else than the holographic image of a lens obtained by producing a hologram of a lens. By directing a ray of light on said image, the same will at a certain distance be focused exactly as if the lens itself were placed at the same point of the hologram. The difference is that the hologram has a thickness of a few microns, is easily produced and reproducible. The next step is to generate a hologram of a lens system produced in this manner. For this purpose, one can proceed in a twofold manner: experimentally and theoretically.

FIG. 8 shows a typical set-up for producing a hologram of a lens or an array of lenses. In the same figure, the reference no. 11 stand for a laser source, 12 for a “beam splitter” device, 13 for a photo-resist film. 14 indicates a tri-dimensional model of the micro-lens system (lens array) to be produced in a holographic form. It should however be mentioned that such a model can be omitted, because the same holographic lenses can be produced by suitably varying, (in an already known manner), the distance “d” between the mirrors while micro-incising the photo-resist film.

A hologram is produced by replicating the various individual holograms, until a master hologram with the same lateral dimensions of a photovoltaic panel is achieved.

Various holograms and layers of holograms can be utilized for focusing light from various lateral angles on photocells. The selection of the concentrating holograms allows the photovoltaic devices to receive a broad variety of wavelengths without any losses in the impinging angle of the light. This large number of receiving angles affords the possibility of receiving light for a large stretch of the day without a need for targeting and solar pursuit systems. This allows achieving an efficiency over 50%. After realizing the optimum holographic lenses, a holographic cliché is produced, which if applied on a cylinder of a holographic embossing machine, incises the plastic film so as to permanently reproduce the micro-incisions of holographic lenses.

In order to further clarify the advantage and distinguishing characteristics of the energy converting system according to the invention, attention is drawn to the following:
The holographic film is composed of an array of micro-lenses whose focus equals the thickness of the protective glass of the standard panel (from 3 to 4 mm);
The film can be laminated directly onto the panel glass, and does not require a production of distancing structures capable of distancing the films of the (holographic or non-holographic) lenses from the underlying photovoltaic panel, because it can even be applied from the inside of the photovoltaic panel;
The film can be produced in spools through an “embossing” system (refer to the formerly mentioned Italian patent) and applied on the glass panel with the same machines utilized for applying the EVA film and the Tedlar®;
The film can be cut and sized in accordance with all the photovoltaic or solar standards;
The film has a thickness varying from 10 to 200 microns, and can be applied directly on the silicon cells, by realizing an ultra-short focus of the micro-lenses;
The film can be treated with dielectric layers, so as to increase and concentrate the transmission of the light passing through it;
The lenticular holographic filth can be applied on photovoltaic cells of any organic and inorganic nature, including the experimental modules and others of a new generation;
In order to realize the master form containing the data of the lenticular holograms, several different photo-sensitive supports such as the photo-resist, the photopolymer, dichromate gels and any other material capable of recording the lenticular holographic microstructures can be used;
The lenticular holographic film offers the possibility of applying structures on glass surfaces that are capable of concentrating greater solar energy in the interior of buildings over the winter period.

1. Integrated system for conveying the maximum quantity of solar energy impinging, over the arc of a day, on a transparent plate of a panel for the conversion of solar energy into another form of energy, as e.g. a photovoltaic panel or a solar panel, or on a transparent plate of a door or of a window, where a plastic film bearing holographic micro-incisions is placed upon the plate, characterized by the fact that said film is placed in intimate contact with the plate and bears holographic micro-incisions that form an array of multi-focal holographic micro-lenses (m1, m2).

2. Integrated system for conveying the maximum quantity of solar energy impinging, over the arc of a day, on a transparent plate of a panel for the conversion of solar energy into another form of energy, as e.g. a photovoltaic panel or a solar panel, or on a transparent plate of a door or of a window, where a plastic film bearing holographic micro-incisions is placed upon the plate, characterized by the fact that a pair of plastic films superimposed on each other is placed in intimate contact with the plate, said films bearing on their inner and outer surfaces micro-undular forms capable of creating a series of micro-lenses (c1, c2) of an off-spherical shape having different refraction indices.

3. Integrated system as per claim 1, for conveying the maximum quantity of solar energy impinging, over the arc of a day, on a transparent plate of a panel for the conversion of solar energy into another form of energy, characterized by the fact that the plastic film bearing multi-focal holographic micro-lenses is composed of an array of micro-lenses, whose focus equals the thickness of the protective glass of the panel.

4. Integrated system as per claim 1, characterized by the fact that the plastic film bearing multi-focal holographic micro-lenses has a thickness variable from 10 to 200 micron and can be applied directly on the silicon cells, by realizing an ultra-short focal distance on the micro-lenses.

5. Integrated system as per claim 1, characterized by the fact that the plastic film is applied on the panel glass with the same machines used for applying an EVA film and a Tedlar® film.

6. Integrated system as per claim 1, characterized by the fact that the plastic film is treated with dielectric layers to increase and concentrate the transmission of light passing through it.

7. Integrated system as per claim 1, characterized by the fact that in order to realize the master form containing the data for the lenticular holograms, various photo-sensitive supports such as a photo-resist, a photo-polymer, dichromate-gels or any other material capable of impressing the lenticular holographic microstructures can be used.

8. Integrated system as per claim 2, characterized by the fact that the plastic film is applied on the panel glass with the same machines used for applying an EVA film and a Tedlar® film.

9. Integrated system as per claim 2, characterized by the fact that the plastic film is treated with dielectric layers to increase and concentrate the transmission of light passing through it.

10. Integrated system as per claim 2, characterized by the fact that in order to realize the master form containing the data for the lenticular holograms, various photo-sensitive supports such as a photo-resist, a photo-polymer, dichromate-gels or any other material capable of impressing the lenticular holographic microstructures can be used.
